(19) United States
(12) Patent Application Publication
(10) Pub. No.: US 2022/0013625 A1
(43) Pub. Date: Jan. 13, 2022

(54) VERTICAL POWER SEMICONDUCTOR DEVICE AND MANUFACTURING METHOD

(71) Applicant: Infineon Technologies AG, Neubiberg (DE)

(72) Inventors: Hans-Joachim Schulze, Taufkirchen (DE); Philipp Kohler-Redlich, Unterhaching (DE); Thomas Laska, München (DE); Franz-Josef Niedernostheide, Hagen Am Teutoburger Wald (DE); Vera van Treek, Unterhaching (DE)

(21) Appl. No.: 17/370,179

(22) Filed: Jul. 8, 2021

(30) Foreign Application Priority Data
Jul. 13, 2020 (DE) 102020118404.2

(51) Int. Cl. H01L 29/06; H01L 29/739; H01L 29/04; H01L 29/10; H01L 29/66; H01L 29/861

(52) U.S. Cl. CPC H01L 29/0607; H01L 29/7397; H01L 29/04; H01L 29/8613; H01L 29/66348; H01L 29/66136; H01L 29/1083

(57) ABSTRACT

A vertical power semiconductor device is proposed. The vertical power semiconductor device includes a semiconductor body including a semiconductor substrate and a semiconductor layer on the semiconductor substrate. The semiconductor body has a first main surface and a second main surface opposite to the first main surface along a vertical direction. The vertical power semiconductor device further includes a drift region in the semiconductor body. A first part of the drift region is arranged in the semiconductor substrate. A second part of the drift region is arranged in the semiconductor layer. The vertical power semiconductor device further includes a field stop region arranged in the semiconductor substrate, wherein a doping concentration of the field stop region averaged along the vertical direction is larger than a doping concentration of the drift region averaged along the vertical direction.

### TECHNICAL FIELD

The present disclosure is related to semiconductor devices, in particular to vertical power semiconductor devices including a semiconductor substrate.

### BACKGROUND

In semiconductor switching devices like IGBTs (insulated gate bipolar transistors) or diodes mobile charge carriers flood a low-doped drift region and form a charge carrier plasma that provides a low on-state resistance. One target of semiconductor device technology lies in the design of semiconductor switching devices having specified switching and voltage blocking characteristics. An impact on the semiconductor switching and voltage blocking characteristics may be caused by impurities in the semiconductor substrate material. Thus, semiconductor device technology development is challenging for meeting target demands on semiconductor switching and voltage blocking characteristics.

There is a need to improve semiconductor switching and voltage blocking characteristics of vertical power semiconductor devices.

### SUMMARY

An example of the present disclosure relates to a vertical power semiconductor device. The vertical power semiconductor device includes a semiconductor body including a semiconductor substrate and a semiconductor layer on the semiconductor substrate. The semiconductor body has a first main surface and a second main surface opposite to the first main surface along a vertical direction. The vertical power semiconductor device further includes a drift region in the semiconductor body. A first part of the drift region is arranged in the semiconductor substrate. A second part of the drift region is arranged in the semiconductor layer. The vertical power semiconductor device further includes a field stop region arranged in the semiconductor substrate. A doping concentration of the field stop region averaged along the vertical direction is larger than a doping concentration of the drift region averaged along the vertical direction.

Another example of the present disclosure relates to a method of manufacturing a vertical power semiconductor device. The method includes providing a semiconductor body by forming a semiconductor layer on a semiconductor substrate. The semiconductor body has a first main surface and a second main surface opposite to the first main surface along a vertical direction. The method further includes forming a drift region in the semiconductor body. A first part of the drift region is arranged in the semiconductor substrate. A second part of the drift region is arranged in the semiconductor layer. The method further includes forming a field stop region arranged in the semiconductor substrate. A doping concentration of the field stop region averaged along the vertical direction is larger than a doping concentration of the drift region averaged along the vertical direction.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the embodiments and are incorporated in and constitute part of this specification. The drawings illustrate embodiments of a vertical power semiconductor device and a method of manufacturing a vertical power semiconductor device and together with the description serve to explain principles of the embodiments. Further embodiments are described in the following detailed description and the claims.

FIG. 1 is a schematic cross-sectional view for illustrating an example of a vertical power semiconductor device.

FIGS. 2A and 2B are schematic cross-sectional views for illustrating examples of a vertical power semiconductor diode and a vertical power IGBT.

FIG. 3 is a schematic graph for illustrating exemplary doping concentration profiles in the vertical power semiconductor device of FIG. 1.

FIG. 4 is a schematic graph for illustrating an exemplary vertical oxygen concentration profile in the vertical power semiconductor device of FIG. 1.

FIG. 5 is a schematic graph for illustrating an exemplary lateral oxygen concentration profile in the vertical power semiconductor device of FIG. 1.

FIGS. 6A to 6C and 7 are cross-sectional views for illustrating a method for manufacturing a vertical power semiconductor device.

### DETAILED DESCRIPTION

In the following detailed description, reference is made to the accompanying drawings, which form a part hereof and in which are shown by way of illustrations specific embodiments in which the invention may be practiced. It is to be understood that other embodiments may be utilized and structural or logical changes may be made without departing from the scope of the present invention. For example, features illustrated or described for one embodiment can be used on or in conjunction with other embodiments to yield yet a further embodiment. It is intended that the present invention includes such modifications and variations. The examples are described using specific language, which should not be construed as limiting the scope of the appending claims. The drawings are not scaled and are for illustrative purposes only. For clarity, the same elements have been designated by corresponding references in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” describes a permanent low-resistive connection between electrically connected elements, for example a direct contact between the concerned elements or a low-resistive connection via a metal and/or heavily doped semiconductor material. The term “electrically coupled” includes that one or more intervening element(s) adapted for signal and/or power transmission may be connected between the electrically coupled elements, for example, elements that are controllable to temporarily provide a low-resistive connection in a first state and a high-resistive electric decoupling in a second state. An ohmic contact is a non-rectifying electrical junction with a linear or almost linear current-voltage characteristic.

The figures illustrate relative doping concentrations by indicating “−” or “+” next to the doping type “n” or “p”. For example, “n−” means a doping concentration that is lower than the doping concentration of an “n”-doping region while an “n+”-doping region has a higher doping concentration than an “n”-doping region. Doping regions of the same relative doping concentration do not necessarily have the same absolute doping concentration. For example, two different “n”-doping regions may have the same or different absolute doping concentrations.

Ranges given for physical dimensions include the boundary values. For example, a range for a parameter y from a to b reads as a≤y≤b. A parameter y with a value of at least c reads as c≤y and a parameter y with a value of at most d reads as y≤d.

The term “on” is not to be construed as meaning only “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate).

An example of a vertical power semiconductor device may include a semiconductor body including a semiconductor substrate and a semiconductor layer on the semiconductor substrate. The semiconductor body has a first main surface and a second main surface opposite to the first main surface along a vertical direction. The semiconductor layer may be formed by at least one epitaxial layer formation process, e.g. an epitaxial layer deposition process such as chemical vapor deposition (CVD). The semiconductor layer may be formed by one or more than one sub-layer, wherein the sub-layers may differ with respect to at least one of thickness and doping, e.g. doping concentration and/or doping concentration profile and/or doping species. Various doping processes may be applied for doping the semiconductor layer, e.g. neutron doping, doping with dopants with shallow or deep energy levels in the semiconductor band gap such as phosphorus, arsenic, antimony, selenium or sulphur or doping with hydrogen-related donors by proton implantation and annealing.

The vertical power semiconductor device may further include a drift region in the semiconductor body. A first part of the drift region may be arranged in the semiconductor substrate and a second part of the drift region may be arranged in the semiconductor layer.

The vertical power semiconductor device may further include a field stop region arranged, at least partly, in the semiconductor substrate. A doping concentration of the field stop region averaged along the vertical direction, e.g. a mean doping concentration of the field stop region, is larger than a doping concentration of the drift region averaged along the vertical direction, e.g. a mean doping concentration of the drift region. For example, an extension of an n-doped drift region along the vertical direction toward the second main surface may end at an interface or at a transition between the drift region and the field stop region. This field stop region may be realized by in-situ doping during the epitaxial deposition step or by implantation of protons or donor-like atoms with a suitable subsequent annealing step.

For example, a doping concentration in the drift region may gradually or in steps increase or decrease with increasing distance to the first main surface at least in portions of its vertical extension. According to other examples, the doping concentration in the drift region may be approximately uniform. For IGBTs based on silicon, a mean doping concentration in the drift region may be between 5×10¹² cm⁻³ and 1×10¹⁵ cm⁻³, for example in a range from 1×10¹³ cm⁻³ to 2×10¹⁴ cm⁻³. A vertical extension of the drift region may depend on voltage blocking requirements, e.g. a specified voltage class, of the vertical power semiconductor device. When operating the vertical power semiconductor device in voltage blocking mode, a space charge region may vertically extend partly or totally through the drift region depending on the blocking voltage applied to the vertical power semiconductor device. When operating the vertical power semiconductor device at or close to the specified maximum blocking voltage, the space charge region may reach or penetrate into the field stop region. The field stop region is configured to prevent the space charge region from further reaching to the cathode or collector at the second main surface of the semiconductor body, for example. In this manner, the drift region may be formed using desired low doping levels and with a desired thickness while achieving soft switching for the semiconductor device thus formed.

The vertical power semiconductor device may be a vertical power semiconductor IGBT, or a vertical power semiconductor reverse conducting (RC) IGBT or a vertical power semiconductor diode having a first load terminal at the first main surface and a second load terminal at the second main surface. When operating the vertical power semiconductor device, a load current flows between the first and second load terminals predominantly along the vertical direction. The vertical power semiconductor device may be configured to conduct load currents of more than 1 A or more than 10 A or even more than 30 A.

The distribution of the drift region and of its doping level over the semiconductor layer and the semiconductor substrate as well as the formation of the field stop region in the semiconductor substrate may allow for improving cosmic radiation ruggedness, switching characteristic, and stability and reproducibility of a device blocking voltage. This may be due to the low or negligible concentration of oxygen-related thermal donors in the epitaxial layer, for example.

For example, a vertical extension of the first part may range from 10% to 90%, or from 20% to 80%, or from 30% to 70% of a vertical extension of the drift region. The drift region thus vertically extends from within the semiconductor layer into the semiconductor substrate. For example, an extension of an n-doped drift region along the vertical direction toward the first main surface may end at a pn junction formed between the n-doped drift region and an anode region, e.g. a bottom side of the anode region, of a vertical power semiconductor diode or may end at a pn junction formed between the n-doped drift region and a body region, e.g. a bottom side of the body region, of a vertical power semiconductor IGBT.

For example, a vertical extension of the drift region may be configured to block voltages ranging from 1.5 kV to 10 kV or from 2 kV to 8 kV or from 3 kV to 7 kV. For example, blocking voltages between load terminals, e.g. between emitter and collector of an IGBT, or between anode and cathode of a diode may be 1.7 kV, 3.3 kV, 4.5 kV, 5.5 kV, 6 kV, 6.5 kV. The blocking voltage may correspond to a voltage class specified in a datasheet of the power semiconductor device, for example.

For example, the semiconductor substrate may be a Czochralski, CZ, semiconductor substrate. In some examples, the CZ semiconductor substrate may be a Magnetic Czochralski, MCZ, semiconductor substrate. In some other examples, the semiconductor substrate may be a float zone (FZ) semiconductor substrate. The MCZ method is the same as the CZ method except that it is carried out within a strong horizontal (HMCZ) or vertical (VMCZ) magnetic field. This serves to control the convection fluid flow, allowing e.g. with the HMCZ method to minimize the mixing between the liquid in the center of the bath with that at the edge. This effectively creates a liquid silicon crucible around the central silicon bath, which can trap much of the oxygen and slow its migration into the crystal. Compared to the standard CZ a lower oxygen concentration can be obtained and the impurity distribution is more homogeneous. The semiconductor layer on the MCZ semiconductor substrate may be an epitaxial semiconductor layer, e.g. a crystalline silicon semiconductor layer.

For example, a vertical extension of the semiconductor layer on the semiconductor substrate may range from 50 μm to 300 μm, or from 100 μm to 200 μm. In a top portion of the semiconductor layer, e.g. a portion of the semiconductor layer adjoining the first main surface, doped semiconductor regions, e.g. an anode region of a diode or a body and source region of an IGBT, may be formed, for example. A predominant part of the vertical extension of the semiconductor layer may form part of the drift region of the vertical power semiconductor device, for example.

For example, a vertical extension of the field stop region may range from 3 μm to 40 μm, or from 5 μm to 30 μm. The field stop region may include one or more doping peaks. For example, a peak concentration of some or all of the doping peaks may increase or decrease with decreasing vertical distance from the second main surface. For example, some doping peaks may differ from one another with respect to a doping species. Examples of n-type dopant species are, inter alia, hydrogen-related donors realized by a proton implantation or a helium implantation in combination with a hydrogen implantation or hydrogen in-diffusion, e.g. TDDs (thermal double donors), phosphorus, arsenic, antimony, selenium or sulphur.

For example, a doping concentration of the first part of the drift region averaged along the vertical direction is larger than a doping concentration of the second part averaged along the vertical direction. For example, the doping concentration may be determined along the vertical direction through the first semiconductor layer and at least partly into the semiconductor substrate by a dopant profiling method, for example depth profiling of dopants using secondary ion mass spectrometry (SIMS) such as classic dynamic SIMS and TOF (time of flight)-SIMS, or spreading resistance profiling (SRP). The scanning probe techniques for 2D-profiling SIMS and SRP are highly sensitive may also complement one another. For example, a doping concentration of the second part averaged along the vertical direction may range from 1×10¹² cm⁻³ to 1×10¹³ cm⁻³. For example, a doping concentration of the first part averaged along the vertical direction may range from 1×10¹³ cm⁻³ to 2×10¹⁴ cm⁻³ or from 2×10¹³ cm⁻³ to 1×10¹⁴ cm⁻³.

For example, a vertical distance between the field stop region and the second main surface along the vertical direction may range from 0 μm to 30 μm or from 100 nm to 20 μm or from 200 nm to 10 μm. For example, in diodes, an averaged doping concentration of the field stop region may increase toward the second main surface up to doping concentrations that are suitable for establishing an ohmic contact to a contact material, e.g. a metal contact, on the second main surface. A highly doped contact region may also be arranged between the field stop region and the contact material on the second main surface, for example. For example, in IGBTs, a collector region having a conductivity type different from the field stop region may be arranged between the field stop region and the second main surface.

For example, an oxygen concentration in at least part of the semiconductor substrate may be smaller than 2.5×10¹⁷ cm⁻³. This may allow for counteracting or avoiding thermal donor formation. Thermal donors based on oxygen may be undesired electrically active donors that may lead to a troublesome increase of the doping concentration in a drift zone that may have a negative impact on the voltage blocking capability and the switching characteristic of the device, for example.

For example, an oxygen concentration in at least part of the semiconductor substrate may increase along the vertical direction toward the second main surface. For example, an oxygen concentration in the semiconductor substrate may be decreased by diffusing oxygen out of the semiconductor substrate by one or more thermal processes, e.g. heating in an oven. Oxygen may be diffused out of the semiconductor substrate before forming the semiconductor layer on the semiconductor substrate, for example. For example, oxygen outdiffusion may be carried out in a temperature range from 1000° C. to 1250° C. or from 1050° C. to 1200° C. for a time period ranging from 30 minutes to 20 hours or from 1 hour to 10 hours Oxygen may be diffused out of the semiconductor substrate though the first and/or second surface of the semiconductor substrate. For example, an oxygen diffusion barrier may be arranged on the first and/or second surface of the semiconductor substrate or parts thereof, e.g. by a patterned oxygen diffusion barrier, for defining the regions where oxygen can be diffused out of the semiconductor substrate by thermal processing.

For example, an oxygen concentration in at least part of the semiconductor substrate may decrease along a lateral direction perpendicular to the vertical direction. For example, oxygen diffusion out of the semiconductor substrate may be enhanced by forming trenches into the semiconductor substrate to increase a surface area where oxygen may diffuse out of, i.e. exit, the semiconductor substrate. The trenches may be formed at the first and/or second surface of the semiconductor substrate. For example, the trenches may be arranged in a regular pattern. A lateral distance between neighboring trenches, e.g. a mesa region between neighboring trenches, may be set smaller than several tens of micrometers, e.g. smaller than 50 μm or smaller than 30 μm or even smaller than 10 μm. After diffusing oxygen out of the semiconductor substrate, the trenches may be filled with silicon, e.g. by lateral and vertical epitaxial layer deposition. The doping concentration of the silicon filled in the trenches could be identical or close to the doping concentration of the substrate. It is also possible to use different doping concentration or even an inverse doping type, i.e. a p-type doping in case of an n-type substrate. Furthermore, the trench pattern can be designed to have a lateral substructure, e.g. lateral variations of the mesa width, the trench distance or the trench depth.

For example, an oxygen concentration in at least part of the semiconductor substrate may include a plurality of minima and maxima alternately disposed along the lateral direction. The location of the maxima and minima with respect to a surface of the semiconductor substrate may be defined by the arrangement of the trenches. For example, along a lateral direction, a maximum of the oxygen concentration may be located at a center of a mesa region between neighboring trenches, and a minimum of the oxygen concentration may be located at a center of or within a trench.

An example of a method for manufacturing a vertical power semiconductor device may include providing a semiconductor body by forming a semiconductor layer on semiconductor substrate. The semiconductor body has a first main surface and a second main surface opposite to the first main surface along a vertical direction. The method may further include forming a drift region in the semiconductor body. A first part of the drift region may be arranged in the semiconductor substrate. A second part of the drift region may be arranged in the semiconductor layer. The method may further include forming a field stop region arranged in the semiconductor substrate. A doping concentration of the field stop region averaged along the vertical direction may be larger than a doping concentration of the drift region averaged along the vertical direction.

For example, a vertical extension of the first part may range from 10% to 90%, or from 20% to 80%, or from 30% to 70% of a vertical extension of the drift region.

For example, the semiconductor layer or part thereof may be formed on the semiconductor substrate by at least one epitaxial layer deposition process up to a vertical extension ranging from 50 μm to 300 μm, or from 100 μm to 200 μm. The semiconductor layer may be formed by at least one epitaxial layer formation process, e.g. an epitaxial layer deposition process such as chemical vapor deposition (CVD). The semiconductor layer may include one or more than one sub-layer, wherein the sub-layers may differ with respect to at least one of thickness and doping, e.g. doping concentration and/or doping concentration profile and/or doping species.

For example, at least part of the semiconductor layer may be formed on the semiconductor substrate by a bonding process, e.g. wafer bonding, using a donor substrate. The donor substrate may be subsequently removed from the semiconductor layer.

For example, the method may further include, before forming the field stop region, reducing a vertical extension of the semiconductor substrate by removing material of the semiconductor substrate starting from the second main surface of the semiconductor substrate. The material of the semiconductor substrate may be removed by abrasive machining, e.g. grinding, and/or etching processes such as dry and/or wet etching. For example, abrasive machining may be used for thinning the semiconductor substrate to a final thickness range. Thereafter, dry or wet etching processes may be used to more precisely set the target thickness of the semiconductor substrate, for example.

For example, the method may further include, before forming the semiconductor layer on the semiconductor substrate, diffusing oxygen out of the semiconductor substrate by thermal processing.

For example, the method may further include, before forming the semiconductor layer on the semiconductor substrate, forming a plurality of trenches into the semiconductor substrate. A lateral distance between neighboring two of the plurality of trenches, e.g. a width of a mesa region between the neighboring two of the plurality of trenches, may be set in a range from 5 μm to 50 μm. For example, the plurality of trenches may be formed at a surface of the semiconductor substrate where the semiconductor layer is subsequently formed. For example, a mesa width may be set smaller than 50 μm, or smaller than 30 μm, or even smaller than 10 μm. The trenches may enhance outdiffusion of oxygen by increasing a surface area where oxygen may be diffused out of the semiconductor substrate, for example. After diffusing oxygen out of the semiconductor substrate, the trenches may be filled with silicon, e.g. by lateral and vertical epitaxial layer deposition.

The examples and features described above and below may be combined.

In the following, further examples of vertical power semiconductor devices and manufacturing methods are explained in connection with the accompanying drawings. Functional and structural details described with respect to the examples above shall likewise apply to the exemplary embodiments illustrated in the figures and described further below.

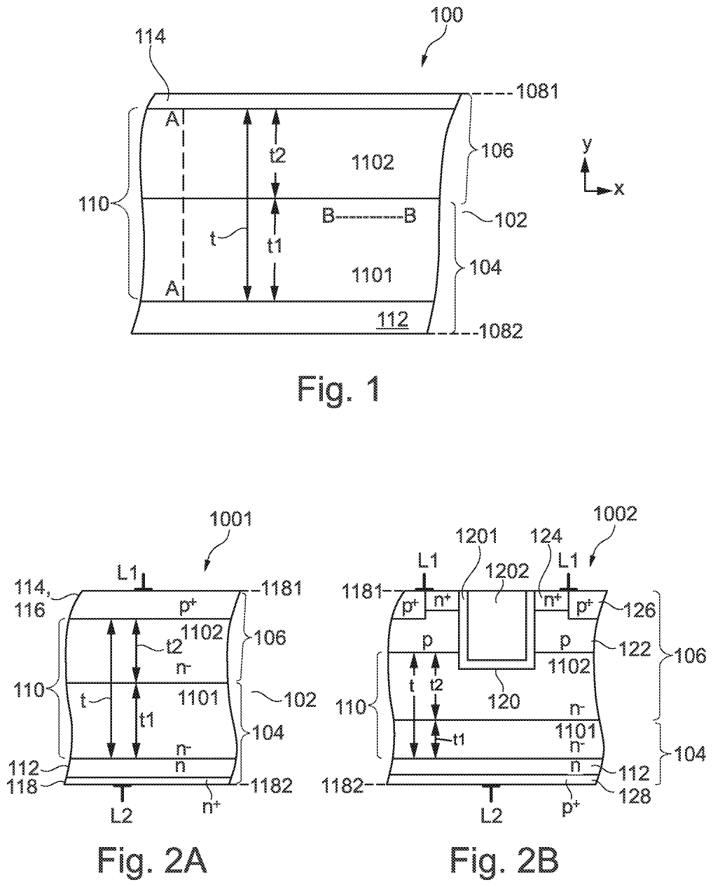

FIG. 1 is a schematic cross-sectional view illustrating a schematic example of a vertical power semiconductor device 100.

The vertical power semiconductor device 100 includes a semiconductor body 102 including a semiconductor substrate 104 and a semiconductor layer 106 on the semiconductor substrate 104. The semiconductor body 102 has a first main surface 1081 and a second main surface 1082 opposite to the first main surface 1081 along a vertical direction y. The semiconductor body 102 includes a drift region 110. A first part 1101 of the drift region 110 is arranged in the semiconductor substrate 104. A second part 1102 of the drift region 110 is arranged in the semiconductor layer 106. A vertical extension t1 of the first part ranges from 10% to 90% of a vertical extension t of the drift region 106, i.e. 0.1×t≤t1≤0.9×t. A field stop region 112 is arranged in the semiconductor substrate 104.

The vertical power semiconductor device 100 may include further structural elements, e.g. in a device portion 114 at the first main surface 1081 or in a portion at the second main surface, depending on the type of device, for example. The schematic-cross sectional views of FIGS. 2A and 2B illustrate further structural elements for the exemplary devices vertical semiconductor power diode (FIG. 2A) and vertical power insulated gate bipolar transistor (FIG. 2B).

Referring to FIG. 2A, the vertical power semiconductor device is a vertical power semiconductor diode 1001 that includes a p⁺-doped anode region 116 in the device portion 114. The drift region 110 is n⁻-doped and includes the first part 1101 in the semiconductor substrate 104 and the second part 1102 in the semiconductor layer 106. The field stop region 112 is n-doped and is arranged in the semiconductor substrate 104 between the drift region 110 and the second main surface 1082. An n⁺-doped region 118 is arranged between the drift region 110 and the second main surface 1082 for providing an electron emitter and an ohmic contact. The drift region 110 extends from the field stop region 112 to the anode region 116 along the vertical direction y. The n⁺-doped contact region 118 may be omitted in case the n-doped field stop region 112 has, or can be manufactured with, a doping concentration at the second main surface that is high enough for enabling ohmic contact properties of an electric contact to a second load electrode L2 at the second main surface 1082. A first load electrode L1 is electrically connected to the anode region 116 at the first main surface 1081.

Referring to FIG. 2B, the vertical power semiconductor device is an insulated gate bipolar transistor 1002 including a gate trench structure 120 that is formed at the first main surface 1081. The gate trench structure 120 includes a gate dielectric 1201 and a gate electrode 1202.

A p-doped body region 122 directly adjoins the gate trench structure 120. An n⁺-doped source region 124 directly adjoins the gate trench structure 120. The body region 122 is electrically connected to the first load electrode L1 through a p⁺-doped body contact region 126. The source region 124 is electrically connected to the first load electrode L1.

The drift region 110 is n⁻-doped and includes the first part 1101 the semiconductor substrate 104 and the second part 1102 in the semiconductor layer 106. The field stop region 112 is n-doped and is arranged in the semiconductor substrate 104 between the drift region 110 and the second main surface 1082. The drift region 110 extends from the field stop region 112 to the body region 122 along the vertical direction y. A p⁺-doped rear side hole emitter region 128 is arranged between field stop region 118 and the second main surface 1082. The rear side emitter region 128 is electrically connected to the second load electrode L2 at a collector side of the IGBT 1002, i.e. at the second main surface 1082. The IGBT 1002 has been illustrated as a vertical trench IGBT. According to other examples, the IGBT 1002 may also be formed as a planar IGBT.

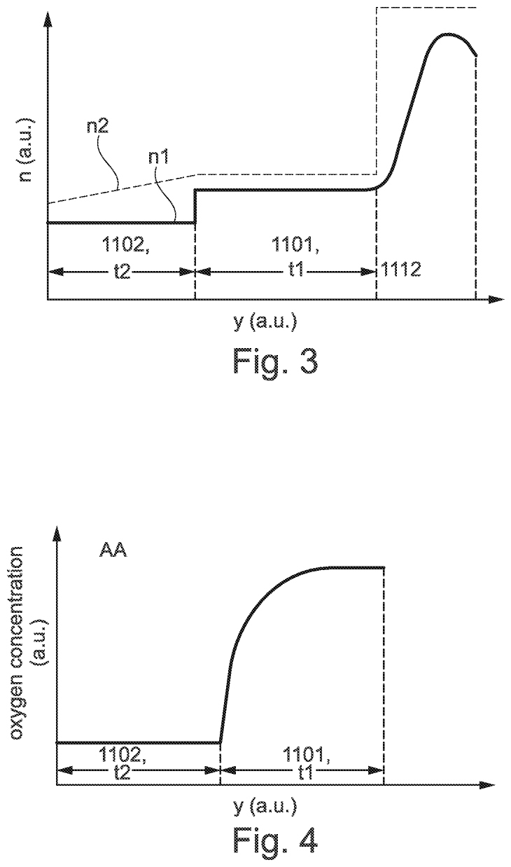

The schematic graph of FIG. 3 illustrates exemplary doping concentration profiles n and doping relations in the first and second part 1101, 1102 of the drift region 110 and in the field stop region 112. A doping concentration n of the first part 1101 averaged along the vertical direction y is larger than an average doping concentration of the second part 1102 averaged along the vertical direction y. Moreover, a doping concentration of the field stop region 112 averaged along the vertical direction y, e.g. a mean doping concentration of the field stop region 122, is larger than a doping concentration of the drift region 110 averaged along the vertical direction y, e.g. a mean doping concentration of the drift region 110 formed by the first and second parts 1101, 1102. For exemplary doping profile n1, n1 is constant in the second part 1102 and stepwise increases to another constant value in the first part 1101. In the field stop region 112, n1 includes a doping peak, e.g. a hydrogen-related doping peak that may be formed by proton implantation and annealing. For exemplary doping profile n2, n2 steadily increases in the second part 1102 to a constant doping concentration in the first part 1101 and stepwise increases to a higher constant doping concentration in the field stop region 112. In view of a thermal budget during device processing, transitions between doping concentrations in the regions described above may be broadened along the vertical direction y by thermal diffusion processes in view of the thermal budget during device processing.

The schematic graph of FIG. 4 schematically illustrates an exemplary oxygen concentration along the vertical direction y of line AA of FIG. 1. In at least part of the semiconductor substrate 104, e.g. in the first part 1101 of the drift region 110, the oxygen concentration increases along the vertical direction toward the second main surface. The oxygen profile may be caused by diffusing oxygen out of the semiconductor substrate for avoiding or suppressing undesired electrically active donors based on oxygen complexes, for example. During the epitaxial deposition of layer 1102 and the subsequent high-temperature steps a certain amount of oxygen may diffuse into layer 1102 which is not illustrated in FIG. 4.

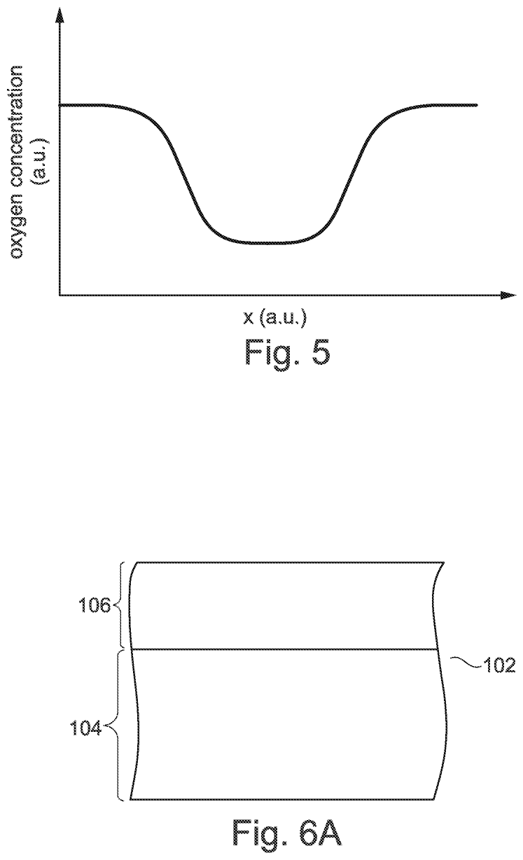

The schematic graph of FIG. 5 schematically illustrates an exemplary oxygen concentration along the vertical direction x of line BB illustrated in FIG. 1. In at least part of the semiconductor substrate 104, the oxygen concentration decreases along a lateral direction x. For example the oxygen concentration in at least part of the semiconductor substrate 104 includes a plurality of minima and maxima alternately disposed along the lateral direction x. The minima and maxima may be formed by diffusing oxygen out through trenches in the semiconductor substrate before forming the semiconductor layer.

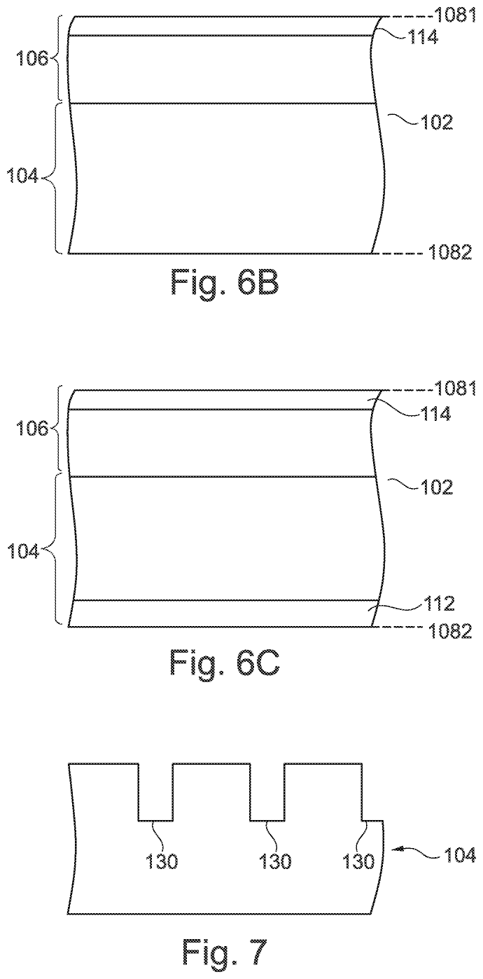

A method for manufacturing a vertical power semiconductor device 100 is schematically illustrated in FIGS. 6A to 6C.

Referring to the schematic cross-sectional view of FIG. 6A, a semiconductor body 102 is provided by forming a semiconductor layer 106 on a semiconductor substrate 104. The semiconductor layer 106 may have a thickness of more than 100 μm, for example. For example, the semiconductor layer 106 may be formed by one or a plurality of epitaxial layer deposition processes. As an alternative or in addition, an epitaxial layer on a donor substrate may be bonded on the semiconductor substrate 104 or on the semiconductor layer 106. The donor substrate may be removed by a separation process, e.g. a smart cut process or by abrasive machining, e.g. grinding, and/or etching processes such as dry and/or wet etching. These processes may be repeated to further increase a final thickness of the semiconductor layer 106, for example.

Referring to the schematic cross-sectional view of FIG. 6B, semiconductor device elements, e.g. an anode region of a diode or a source region, or body region, or gate structure of an IGBT, may be formed in or on a device portion 114 at the fist main surface 1081. Further structural device elements, e.g. a wiring area above the first main surface 1081, may be formed.

Referring to the schematic cross-sectional view of FIG. 6C, a vertical extension, i.e. thickness, of the semiconductor substrate 104 may be reduced by one or more material removal processes. Thereafter, dopant may be introduced through the second main surface 1082 into the semiconductor substrate 104 for forming the field stop region 112. Further processes may follow for finalizing the vertical power semiconductor device.

Referring to the schematic cross-sectional view of FIG. 7, a plurality of trenches 130 may be formed into the semiconductor substrate 104 before forming the semiconductor layer 106 on the semiconductor substrate 104 as is illustrated in FIG. 6A. Oxygen may be diffused out of the semiconductor substrate 104 by thermal processing and the trenches may be filled by semiconductor material before forming the semiconductor layer 106 on the semiconductor substrate 104.

Conductivity type of the doped regions illustrated in the examples above may also be reversed, i.e. a region illustrated as n-doped may be p-doped, and a region illustrated as p-doped may be n-doped, for example.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A vertical power semiconductor device, comprising:
a semiconductor body including a semiconductor substrate and a semiconductor layer on the semiconductor substrate, wherein the semiconductor body has a first main surface and a second main surface opposite to the first main surface along a vertical direction;
a drift region in the semiconductor body, wherein a first part of the drift region is arranged in the semiconductor substrate, and a second part of the drift region is arranged in the semiconductor layer;
a field stop region arranged in the semiconductor substrate, wherein a doping concentration of the field stop region averaged along the vertical direction is larger than a doping concentration of the drift region averaged along the vertical direction.

2. The vertical power semiconductor device of claim 1, wherein a vertical extension of the first part ranges from 10% to 90% of a vertical extension of the drift region.

3. The vertical power semiconductor device of claim 1, wherein a vertical extension of the drift region is configured to block voltages ranging from 1.5 kV to 10 kV.

4. The vertical power semiconductor device of claim 1, wherein the semiconductor substrate is a Czochralski (CZ) semiconductor substrate.

5. The vertical power semiconductor device of claim 4, wherein the CZ semiconductor substrate is a Magnetic Czochralski (MCZ) semiconductor substrate.

6. The vertical power semiconductor device of claim 1, wherein a doping concentration of the first part averaged along the vertical direction is larger than an average doping concentration of the second part averaged along the vertical direction.

7. The vertical power semiconductor device of claim 1, wherein a doping concentration of the second part averaged along the vertical direction ranges from 1×10¹² cm⁻³ to 1×10¹³ cm⁻³.

8. The vertical power semiconductor device of claim 1, wherein a doping concentration of the first part averaged along the vertical direction ranges from 1×10¹³ cm⁻³ to 2×10¹⁴ cm⁻³.

9. The vertical power semiconductor device of claim 1, wherein a vertical distance between the field stop region and the second main surface along the vertical direction ranges from 0 μm to 30 μm.

10. The vertical power semiconductor device of claim 1, wherein an oxygen concentration in at least part of the semiconductor substrate is smaller than 2.5×10¹⁷ cm⁻³.

11. The vertical power semiconductor device of claim 1, wherein an oxygen concentration in at least part of the semiconductor substrate increases along the vertical direction toward the second main surface.

12. The vertical power semiconductor device of claim 1, wherein an oxygen concentration in at least part of the semiconductor substrate decreases along a lateral direction perpendicular to the vertical direction.

13. The vertical power semiconductor device of claim 1, wherein an oxygen concentration in at least part of the semiconductor substrate includes a plurality of minima and maxima alternately disposed along a lateral direction perpendicular to the vertical direction.

14. A method for manufacturing a vertical power semiconductor device, the method comprising:
providing a semiconductor body by forming a semiconductor layer on a semiconductor substrate, wherein the semiconductor body has a first main surface and a second main surface opposite to the first main surface along a vertical direction;
forming a drift region in the semiconductor body, wherein a first part of the drift region is arranged in the semiconductor substrate and a second part of the drift region is arranged in the semiconductor layer; and
forming a field stop region arranged in the semiconductor substrate, wherein a doping concentration of the field stop region averaged along the vertical direction is larger than a doping concentration of the drift region averaged along the vertical direction.

15. The method of claim 14, wherein a vertical extension of the first part ranges from 10% to 90% of a vertical extension of the drift region.

16. The method of claim 14, wherein at least part of the semiconductor layer is formed on the semiconductor substrate by at least one epitaxial layer deposition process up to a vertical extension ranging from 50 μm to 300 μm.

17. The method of claim 14, wherein at least part of the semiconductor layer is formed on the semiconductor substrate by a bonding process using a donor substrate.

18. The method of claim 14, further comprising:
before forming the field stop region, reducing a vertical extension of the semiconductor substrate by removing material of the semiconductor substrate.

19. The method of claim 14, further comprising:
before forming the semiconductor layer on the semiconductor substrate, diffusing oxygen out of the semiconductor substrate by thermal processing.

20. The method of claim 19, further comprising:
before forming the semiconductor layer on the semiconductor substrate, forming a plurality of trenches into the semiconductor substrate.

21. The method of claim 20, wherein a lateral distance between neighboring two of the plurality of trenches is set in a range from 5 μm to 50 μm.

22. The method of claim 14, wherein the semiconductor substrate is a Czochralski (CZ) semiconductor substrate.

23. The method of claim 22, wherein the CZ semiconductor substrate is a Magnetic Czochralski (MCZ) semiconductor substrate.
